(19) United States
(12) Patent Application Publication
(10) Pub. No.: US 2003/0186534 A1
(43) Pub. Date: Oct. 2, 2003

(54) Method for manufacturing semiconductor device using dual-damascene techniques

(76) Inventor: Hidetaka Nambu, Kanagawa (JP)

Correspondence Address: KATTEN MUCHIN ZAVIS ROSENMAN, 575 MADISON AVENUE, NEW YORK, NY, 10022-2585, US

(21) Appl. No.: 10/397,784

(22) Filed: Mar. 26, 2003

(30) Foreign Application Priority Data
Mar. 26, 2002 (JP) 2002-086954

(51) Int. Cl. H01L 21/4763

(52) U.S. Cl. 438/633; 438/634

(57) ABSTRACT

Formed on a substrate are an inorganic interlayer film, an organic interlayer film, a lower mask made of silicon oxide and an upper mask made of silicon nitride in this order. An opening is formed in the upper mask. Then, a cover mask made of silicon oxynitride and having a film thickness of 20 to 100 nm is formed on the upper mask. Thereafter, an Anti-Reflection Coating film and a resist film are formed thereon. Subsequently, the Anti-Reflection Coating film, the cover mask and the lower mask is etched using the resist film as a mask. Then, the organic interlayer film and the inorganic interlayer film are etched using the cover mask as a mask to form a via hole. Simultaneously, the cover mask is removed to make the upper mask exposed. Thereafter, the organic interlayer film is etched using the upper mask as a mask to form an interconnect trench.

### BACKGROUND OF THE INVENTION

1. Field of the Invention

The present invention relates to a method for manufacturing a semiconductor device using dual-damascene techniques and employing an inorganic and low dielectric constant film as an interlayer film used in formation of via, and particularly to a method for manufacturing a semiconductor device employing an inorganic/low dielectric constant film as an interlayer film used in formation of via and an organic/low dielectric constant film as an interlayer film used in formation of interconnect line, those different films, i. e., inorganic and organic films, forming the hybrid configuration of insulation film in the semiconductor device.

2. Description of the Related Art

Conventionally, a semiconductor device such as a Large Scale Integrated circuit (LSI) has multi-layer interconnects formed on a semiconductor substrate to connect elements to one another. The multi-layer interconnects are configured to have interconnect layers and via layers alternately laminated. The interconnect layer is formed to have an interconnect line filled into an interlayer insulation film and the via layer is formed to have a via filled into the interlayer insulation film to connect the above-stated interconnect lines to one another.

In recent years, the semiconductor device has been required to operate at higher rate and at lower power. For this reason, a low dielectric constant film (Low-K film) is employed as an interlayer insulation film in many cases. The low dielectric constant film is classified broadly into two films, i. e., an organic low dielectric constant film made of an organic material and an inorganic low dielectric constant film made of an inorganic material. When the organic low dielectric constant film is combined with a hard mask made of an inorganic material, the high etching selectivity can be achieved between the film and the hard mask. For this reason, using an organic low dielectric constant film allows a hard mask and a resist film to be formed thinner, producing a beneficial effect on processing performance.

Furthermore, copper or copper alloy (hereinafter, referred generally to as copper), which is superior in conductivity and chemical stability, and further, exhibits superior electro-migration resistance and stress-migration resistance, is preferably employed as a material used in formation of interconnect line and via. However, an interconnect line and a via, both made of copper, are chemically stable and therefore, are not easily processed. That is why an interconnect line and a via are formed in a damascene process. That is, an interconnect trench and a via hole are formed in an interlayer insulation film and a film made of copper is deposited over the interlayer insulation film including the interconnect trench and the via hole, and then, unnecessary copper film on the interlayer insulation film is removed to leave the copper film only within the interconnect trench and the via hole, thereby forming an interconnect line and a via. For the purpose of formation of extremely fine and multi-layer interconnect structure, a dual-damascene process for simultaneously forming a interconnect line and a via is preferably employed.

Japanese Patent Application 2001-156170 discloses a technique for forming multi-layer interconnects consisting of two interlayer insulation films in a dual-damascene process by using a Dual Hard Mask (DHM). FIGS. 1A to 1E and FIGS. 2A to 2E are cross sectional views illustrating a conventional method, disclosed in Japanese Patent Application 2001-156170, for manufacture of multi-layer interconnects in the order of process steps.

As shown in FIG. 1A, the method according to the conventional technique includes: forming a passivation film 111 on a substrate 110; and forming a first organic interlayer film 112. The first organic interlayer film 112 is made of polyarylether. An etch stop layer 113 is formed on the first organic interlayer film 112 and a second organic interlayer film 114 is formed thereon. The second organic interlayer film 114 is also made of polyarylether. Then, a lower mask 115 made of silicon oxide is formed on the film 114 and an upper mask 116 made of silicon nitride is formed thereon. Thus, the lower mask 115 and the upper mask 116 constitute a two-layered mask (DHM). Thereafter, a resist mask 131 having an opening 132 for formation of interconnect trench is formed on the upper mask 116.

As shown in FIG. 1B, the upper mask 116 is etched using the resist mask 131 as a mask to form a trench pattern 117. Then, as shown in FIG. 1C, an insulation film 118 made of TaN is formed on the upper mask 116 and a portion of the lower mask 115 exposed through the upper mask 116. Thereafter, as shown in FIG. 1D, the insulation film 118 is etched to form sidewalls 119 made of TaN on the side surfaces of the trench pattern 117 of the upper mask 116. Then, as shown in FIG. 1E, a resist mask 133 having an opening 134 for formation of via hole is formed. In this case, when viewing the substrate from a direction vertical to the substrate, the opening 134 of the resist mask 133 is located within the opening of the trench pattern 117.

As shown in FIG. 2A, the lower mask 115 is etched using the resist mask 133 as a mask to form a via hole pattern 120. Then, as shown in FIG. 2B, the etching operation is further performed to form a via hole pattern 120 in the second organic interlayer film 114. In this case, the resist mask 133 is simultaneously removed. After removal of the resist mask 133, the lower mask 115 serves as a mask.

Thereafter, as shown in FIG. 2C, the lower mask 115 is etched using the upper mask 116 and the sidewall 119 as a mask. In this case, the etch stop layer 113 is also etched and removed, and thus the removed portion of the layer 113 forms an upper portion of a via hole 121. Then, as shown in FIG. 2D, the second organic interlayer film 114 is etched using the upper mask 116 and the sidewall 119 as a mask to form an interconnect trench 122. Through the above-described etching step, the first organic interlayer film 112 is also etched to form a primary portion of the via hole 121.

Subsequently, as shown in FIG. 2E, a portion of the passivation film 111, which portion is exposed through the bottom of the via hole 121, is etched and removed using the lower mask 115 and the etch stop layer 113 as a mask. In this case, the upper mask 116 and the sidewall 119 are also etched and removed. Then, the lower mask 115 is removed. Thereafter, a metal material is formed within the via hole 121 and the interconnect trench 122. Then, the excess metal material on the second interlayer film 114 is removed. The above-described method allows formation of multi-layer interconnects consisting of two organic interlayer insulation films.

However, the above-described conventional technique has the following drawbacks. That is, when both first and second interlayer films, the first interlayer film being located lower than the second interlayer film, are realized by employing an organic interlayer insulation film, heat removal from the device having the first and second interlayer films formed therein becomes insufficient, making the characteristics of device degraded. Furthermore, since the organic interlayer insulation film is significantly expensive, employing the organic interlayer insulation film for formation of two interlayer insulation films unfavorably increases the cost of an entire semiconductor device.

### SUMMARY OF THE INVENTION

An object of the present invention is to provide a method for manufacturing a semiconductor device using dual-damascene techniques in order to make the semiconductor device have a high heat removal ability and fabricated at a low cost, and further, suitable for micro-fabrication.

A method for manufacturing a semiconductor device using dual-damascene techniques according to the first aspect of the present invention, comprises the steps of: forming in order a first interlayer film made of a first inorganic low dielectric constant film and a second interlayer film made of one of an organic low dielectric constant film and a second inorganic low dielectric constant film, the second inorganic low dielectric constant film being characterized such that an etching rate of the second inorganic low dielectric constant film is different from that of the first inorganic low dielectric constant film; forming a lower mask on the second interlayer film; forming an upper mask having an interconnect trench formed therein on the lower mask; forming a cover mask over surfaces of the lower mask and the upper mask; etching the cover mask, the lower mask and the second interlayer film using as a mask a resist film having an opening formed therein for formation of a via hole; etching the first interlayer film using the cover mask as a mask to form a via hole while removing the cover mask to make the upper mask exposed; and etching the second interlayer film using the upper mask as a mask to form an interconnect trench.

In the first aspect of the present invention, since the first interlayer film is formed of a low dielectric constant film, the device is able to further enhance its heat removal ability and to further lower the cost thereof in comparison with the case where both the first and second interlayer films are made of an organic low dielectric constant film. In addition, since the cover mask is formed on the upper mask and the first interlayer film is etched using the cover mask as a mask to form a via hole while the cover mask is removed to make the upper mask exposed, the cover mask is able to protect the upper mask from being etched during the step of etching the first interlayer film and at the same time, make the upper mask exposed upon completion of the etching step. This allows the upper mask to be used as a mask and to be prevented from disappearing during the step of etching the second interlayer film to form an interconnect trench. This also enables the interconnect trench to be formed with high accuracy. As a result, formation of an interconnect line having a narrower width becomes possible, enabling a semiconductor device to achieve high integration. Note that the cover mask is not a normal mask but a film that is progressively etched during an etching step.

A method for manufacturing a semiconductor device using dual-damascene techniques according to the second aspect of the present invention, comprises the steps of: forming in order a first interlayer film made of a first inorganic low dielectric constant film and a second interlayer film made of one of an organic low dielectric constant film and a second inorganic low dielectric constant film, the second inorganic low dielectric constant film being characterized such that an etching rate of the second inorganic low dielectric constant film is different from that of the first inorganic low dielectric constant film; forming a lower mask on the second interlayer film; forming an upper mask having an interconnect trench formed therein on the lower mask; forming a cover mask made of a material over surfaces of the lower mask and the upper mask, the material being characterized such that an etching rate of the material is between etching rates of the lower mask and the upper mask; etching the cover mask, the lower mask and the second interlayer film using as a mask a resist film having an opening formed therein for formation of a via hole; etching the first interlayer film using the cover mask as a mask to form a via hole; and etching the second interlayer film using the upper mask as a mask to form an interconnect trench.

In the second aspect of the present invention, since the first interlayer film is formed of a low dielectric constant film, the device is able to further enhance its heat removal ability and to further lower the cost thereof in comparison with the case where both the first and second interlayer films are made of an organic low dielectric constant film. In addition, since the cover mask is formed of a material whose etching rate is between etching rates of the lower mask and the upper mask and the etching rate of the cover mask is made higher than that of the upper mask, the cover mask is able to protect the upper mask from being etched until half of the step of etching the first interlayer film has completed in the step of etching the first interlayer film to form a via hole. Furthermore, since the etching rate of the cover mask is made lower than that of the lower mask, only the cover mask is removed to make the upper mask exposed upon completion of the etching step in the step of etching the first interlayer film using the cover mask as a mask to form a via hole. This allows the upper mask to be used as a mask and to be prevented from disappearing during the step of etching the second interlayer film to form an interconnect trench. This also enables the interconnect trench to be formed with high accuracy. As a result, formation of an interconnect line having a narrower width in a semiconductor device becomes possible, enabling the semiconductor device to achieve high integration.

A method for manufacturing a semiconductor device using dual-damascene techniques according to the third aspect of the present invention, comprises the steps of: forming in order a first interlayer film made of a first inorganic low dielectric constant film, an etch stop film and a second interlayer film made of one of an organic low dielectric constant film and a second inorganic low dielectric constant film; forming a lower mask on the second interlayer film; forming an upper mask having an interconnect trench formed therein on the lower mask; forming a cover mask over surfaces of the lower mask and the upper mask; etching the cover mask, the lower mask and the second interlayer film using as a mask a resist film having an opening formed therein for formation of a via hole; etching the first interlayer film using the cover mask as a mask to form a via hole while removing the cover mask to make the upper mask exposed; and etching the second interlayer film using the upper mask as a mask to form an interconnect trench.

A method for manufacturing a semiconductor device using dual-damascene techniques according to the fourth aspect of the present invention, comprises the steps of: forming in order a first interlayer film made of a first inorganic low dielectric constant film, an etch stop film and a second interlayer film made of one of an organic low dielectric constant film and a second inorganic low dielectric constant film; forming a lower mask on the second interlayer film; forming an upper mask having an interconnect trench formed therein on the lower mask; forming a cover mask made of a material over surfaces of the lower mask and the upper mask, the material being characterized such that an etching rate of the material is between etching rates of the lower mask and the upper mask; etching the cover mask, the lower mask and the second interlayer film using as a mask a resist film having an opening formed therein for formation of a via hole; etching the first interlayer film using the cover mask as a mask to form a via hole; and etching the second interlayer film using the upper mask as a mask to form an interconnect trench.

Furthermore, preferably, the methods according to the first to fourth aspects of the present invention further include the step of forming an Anti-Reflection Coating film on the cover mask after formation of the cover mask, in which the resist film is formed after formation of the Anti-Reflection Coating film. This allows the resist film to have a pattern formed therein with high accuracy.

Additionally, the method according to the present invention further is constructed such that the step of etching the cover mask, the lower mask and the second interlayer film using as a mask a resist film having an opening formed therein for formation of a via hole includes the steps of: etching the cover mask and the lower mask using the resist film as a mask; and etching the second interlayer film using the resist film as a mask while removing the resist film to make the cover mask exposed. This enables each of the process conditions for etching the corresponding films to be optimized and eliminates the need for an additional step of removing the resist film since the resist film is simultaneously removed when etching the second interlayer film.

Moreover, the method according to the present invention further is constructed such that the cover mask is made of at least one selected from a group consisting of silicon oxynitride, silicon nitride, silicon carbide, silicon carbonitride and silicon oxide. This makes the stability of the cover mask improved. More preferably, the lower mask is made of silicon oxide, the upper mask is made of silicon nitride and the cover mask is made of silicon oxynitride.

Furthermore, the method according to the first aspect of the present invention further is constructed such that the cover mask is formed to have a film thickness of 20 to 100 nm. This makes easy the operation for removing the cover mask to make the upper mask exposed while protecting the upper mask from being etched in the step of etching the first interlayer film using the cover mask as a mask to form a via hole.

As is shown in the detailed description described above, according to the present invention, in the method for manufacturing a semiconductor device, since the interlayer film used in formation of via hole is formed of an inorganic interlayer film, the device is able to enhance its heat removal ability and lower the manufacturing cost thereof, and further, to prevent the upper mask from being etched during the step of etching the inorganic interlayer film and at the same time make the upper mask exposed upon completion of the etching step, allowing interlayer films used in formation of interconnect lines to finely be processed. As a consequence, a semiconductor device that has densely integrated elements formed therein and is superior in heat removal, and further, is fabricated in low cost can be manufactured.

### BRIEF DESCRIPTION OF THE DRAWINGS

FIGS. 1A to 1E are cross sectional views of multi-layer interconnects, illustrating a method for manufacturing conventional multi-layer interconnects, disclosed in Japanese Patent Application 2001-156170, in the order of process steps;

FIGS. 2A to 2E are cross sectional views of multi-layer interconnects, illustrating a method for manufacturing the conventional multi-layer interconnects in the order of process steps that are located subsequent to the step shown in FIG. 1E;

FIGS. 3A to 3C are cross sectional views of a semiconductor device, illustrating a method for manufacturing a semiconductor device using dual-damascene techniques according to an embodiment of the present invention in the order of process steps;

FIGS. 4A to 4C are cross sectional views of a semiconductor device, illustrating a method for manufacturing a semiconductor device using dual-damascene techniques according to the embodiment in the order of process steps that are located subsequent to the step shown in FIG. 3C;

FIGS. 5A to 5C are cross sectional views of a semiconductor device, illustrating a method for manufacturing a semiconductor device using dual-damascene techniques according to a comparative example associated with the present invention in the order of process steps; and

FIGS. 6A to 6C are cross sectional views of a semiconductor device, illustrating a method for manufacturing a semiconductor device using dual-damascene techniques according to the comparative example in the order of process steps that are located subsequent to the step shown in FIG. 5C.

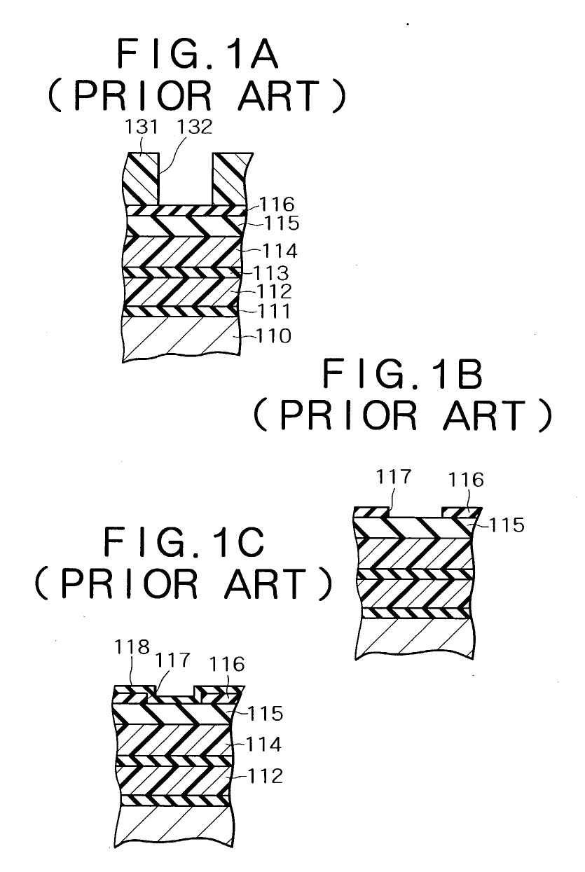

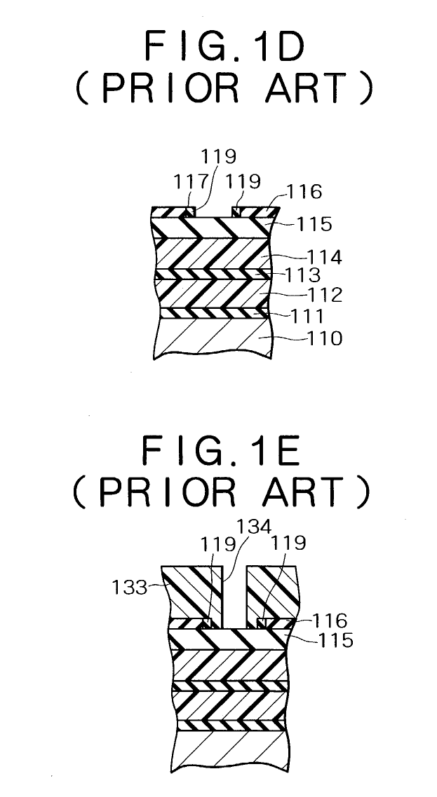

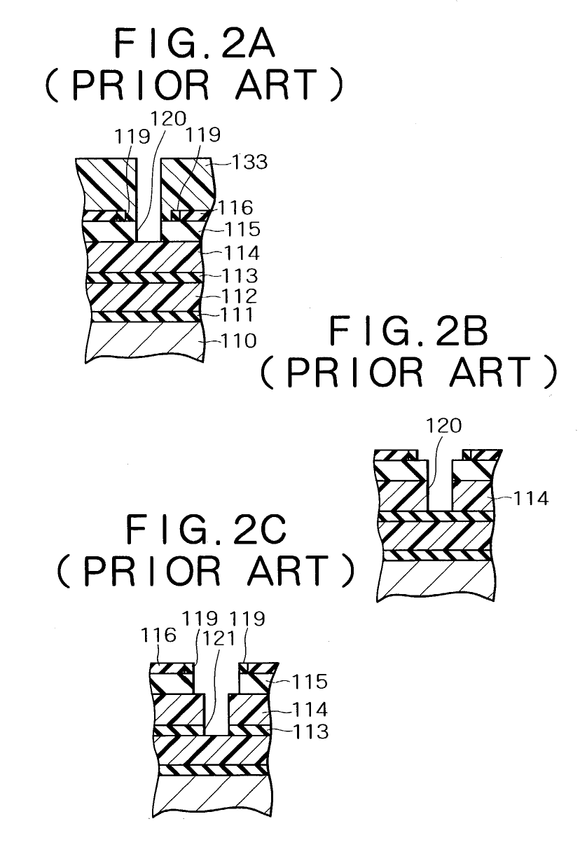

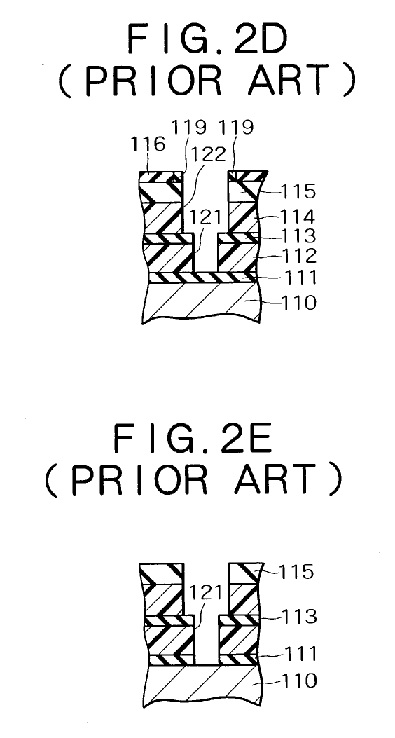

### DETAILED DESCRIPTION OF THE PREFERRED EMBODIMENTS

Embodiments of the present invention will be explained in detail below with reference to the attached drawings.

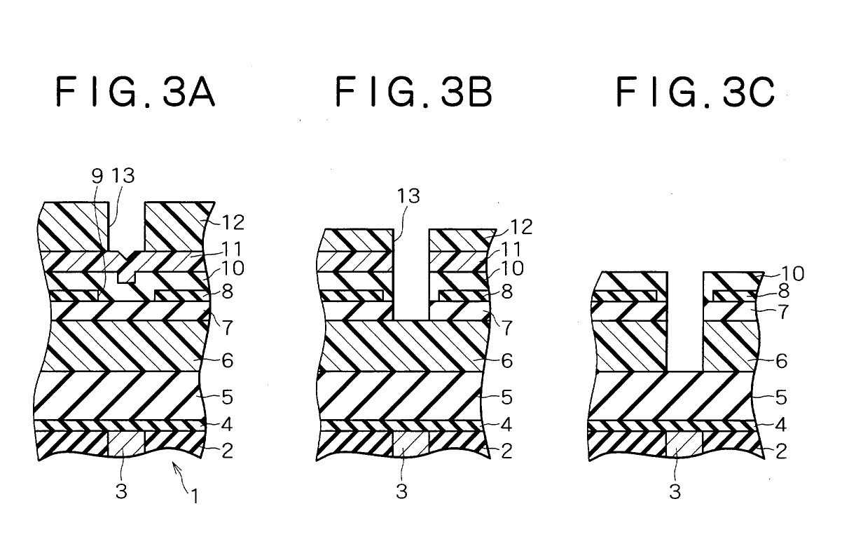

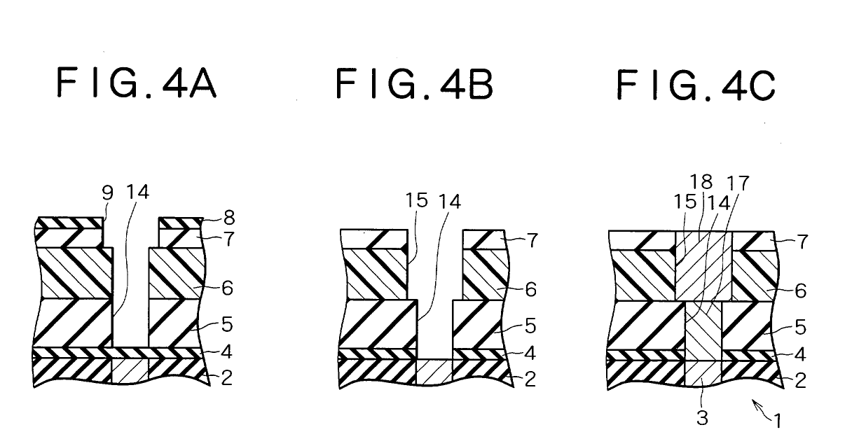

FIGS. 3A to 3C and FIGS. 4A to 4C are cross sectional views illustrating a method for manufacturing a semiconductor device using dual-damascene techniques in accordance with the present invention in the order of process steps.

First, as shown in FIG. 3A, a substrate 1 having an interconnect layer 2 formed in a surface layer thereof is prepared. An interconnect line 3 made of, for example, copper or copper alloy (hereinafter, referred to generally as copper) is embedded in the interconnect layer 2. Then, a stopper film 4 made of, for example, silicon oxide is formed on the substrate 1 and an inorganic interlayer film 5 is formed on the stopper film 4. The inorganic interlayer film 5 is formed of a low dielectric constant film consisting of an inorganic material by depositing by a plasma CVD (Chemical Vapor Deposition) process, for example, Black Diamond supplied by Applied Materials Inc. to a thickness of, for example, 350 nm. Note that the inorganic interlayer film 5 may be formed by depositing Coral supplied by Novellus Systems Inc., or Aurola supplied by ASM. Note that the previously described materials, i. e., Black Diamond, Coral and Aurola, all are a carbon-containing silicon oxide film (SiOC film).

Thereafter, an organic interlayer film 6 is formed on the inorganic interlayer film 5. The organic interlayer film 6 is formed of a low dielectric constant film consisting of an organic material. The organic interlayer film 6 is formed by spin-coating, for example, SiLK supplied by The Dow Chemical Company to a thickness of, for example, 300 nm. Note that the organic interlayer film 6 may be formed using Flare supplied by Honeywell Inc.. Furthermore, an intermediate bonding layer (not shown) may be interposed between the inorganic interlayer film 5 and the organic interlayer film 6. Note that the above-described SiLK is polyphenylene and the above-described Flare is polyarylether.

Subsequently, a lower mask 7 is formed on the organic interlayer film 6. The lower mask 7 is formed by depositing a silicon oxide film to a thickness of, for example, 120 nm. Then, an upper mask 8 is formed on the lower mask 7. The upper mask 8 is formed by depositing, for example, a silicon nitride film to a thickness of, for example, 80 nm and forming a pattern in the silicon nitride film. The pattern thus formed allows an interconnect trench to be formed in the organic interlayer film 6 in a later process step. That is, the upper mask 8 has an opening 9 corresponding to a region through which the interconnect trench is later formed in the organic interlayer film 6. The lower mask 7 and the upper mask 8 form a two-layered mask (DHM).

Subsequently, a cover mask 10 is formed over the upper mask 8. The cover mask 10 is formed by depositing by plasma CVD, for example, a silicon oxynitride film to a thickness of, for example, 20 to 100 nm. In this case, formed on an upper surface of the cover mask 10 is a concave-convex profile, following the profile of the upper mask 8 in which a pattern is formed. In this case, assume that the etching rate of the cover mask 10 is lower than that of the lower mask 7 and higher than that of the upper mask 8.

Thereafter, an Anti-Reflection Coating (ARC) film 11 is formed on the cover mask 10 and a resist film 12 is formed thereon. In this case, formed on an upper surface of the ARC film 11 is a concave-convex profile, following the profile of the upper surface of the cover mask 10. Then, a pattern used in formation of via hole is formed in the resist film 12 to form an opening 13. That is, the opening 13 is formed in a region through which a via hole is later formed in the inorganic interlayer film 5. Accordingly, when viewing the substrate 1 from a direction vertical thereto, the opening 13 of the resist film 12 is ideally located inside the opening 9 of the upper mask 8. However, in some cases, a relative displacement of the opening 13 with respect to the opening 9 occurs, causing a portion of the opening 9 of the upper mask 8 to be in line with the opening 13 or be positioned inside the opening 13 at worst.

Subsequently, as shown in FIG. 3B, the ARC film 11, the cover mask 10 and the lower mask 7 are etched using the resist film 12 as a mask in this order and the corresponding portions of those three films are selectively removed. Note that when the above-described relative displacement occurs, the upper mask 8 is also etched through the opening of the resist film 12. In this case, an etching gas containing, for example, CF₄/Ar/O₂ is used.

Thereafter, as shown in FIG. 3C, the organic interlayer film 6 is etched using the cover mask 10 as a mask and the corresponding portion of the film 6 is selectively removed. In this case, an etching gas containing, for example, N₂/H₂ is used. The etching step allows the resist film 12 and the ARC film 11 (refer to FIG. 3B) to be etched and removed.

Then, the inorganic interlayer film 5 is etched using the cover mask 10 as a mask and the corresponding portion of the film 5 is selectively removed. In this case, an etching gas containing, for example, C₅F₈/Ar/O₂ is used. This makes the etching rate of the cover mask 10 made of, for example, silicon oxynitride becomes higher than that of the upper mask 8 made of, for example, silicon nitride. For this reason, the cover mask 10 is different from a normal mask and is gradually etched and removed during the etching step.

As a result, as shown in FIG. 4A, a via hole 14 is formed in the inorganic interlayer film 5. In this case, the size of the via hole 14 is limited by the via hole pattern that is formed in the organic interlayer film 6. Furthermore, as described above, through this etching step, the cover mask 10 is removed and the upper mask 8 is exposed to the outside. Simultaneously, the lower mask 7 is etched using the upper mask 8 as a mask to form in the lower mask 7 an opening having the profile of interconnect line.

Subsequently, as shown in FIG. 4B, the organic interlayer film 6 is etched using the upper mask 8 as a mask and the corresponding portion of the film 6 is selectively removed. In this case, an etching gas containing, for example, N₂/H₂ is used. Through this etching step, an interconnect trench 15 is formed in the organic interlayer film 6. Then, a portion of the stopper film 4 exposed through the bottom of the interconnect trench 15 is etched by using a gas containing CHF₃/Ar/O₂ as an etching gas and the portion thereof is removed. Through this etching step, the upper mask 8 is removed.

Subsequently, a film made of, for example, copper is deposited over the surface of the substrate including inner portions of the via hole 14 and the interconnect trench 15.

Then, the film formed on the organic interlayer film 6 is removed using Chemical Mechanical Polishing (CMP) to leave the copper within the via hole 14 and the interconnect trench 15. Thus, a via 17 and an interconnect line 18, both of which are made of copper, are formed within the via hole 14 and the interconnect trench 15, respectively. In this case, the width of the interconnect line 18 is made to be, for example, 140 nm. Note that the lower mask 7 serves to 10 prevent the erosion of the organic interlayer film 6 during the CMP step.

As described above, according to the embodiment, multi-layer interconnects can be formed and a semiconductor device can be manufactured. As shown in FIG. 4C, the multi-layer interconnects include the stopper film 4 formed on the substrate 1 and the inorganic interlayer film 5 formed on the stopper film 4. The via hole 14 is formed in the stopper film 4 and the inorganic interlayer film 5, and the via 17 is formed within the via hole 14. Furthermore, the organic interlayer film 6 is formed on the inorganic interlayer film 5 and the lower mask 7 is formed on the organic interlayer film 6. The interconnect trench 15 is formed in the organic interlayer film 6 and the lower mask 7, and the interconnect line 18 is formed within the interconnect trench 15. The interconnect line 18 is connected to the via 17 and the via 17, in turn, is connected to the interconnect line 3 formed in the surface layer of the substrate 1.

It should be appreciated that when assuming the film thickness of the cover mask 10, shown in FIG. 3A, before being etched is less than 20 nm, in the step of etching the inorganic interlayer film 5 using the cover mask 10, shown in FIG. 4A, as a mask, the cover mask 10 is removed at the beginning stage of the etching step and then the upper mask 8 comes to be exposed to an etching gas during the etching step for a long time, whereby an extent to which the upper mask 8 is protected from being etched decreases. In contrast, when the film thickness of the cover mask 10 before being etched is greater than 100 nm, in the step shown in FIG. 4A, removal of the cover mask 10 becomes difficult. Accordingly, it is preferable to make the film thickness of the cover mask 10 before being etched range from 20 to 100 nm.

In the embodiment, since an inorganic interlayer film made of an inorganic material is employed as an interlayer film that is used to form a via, heat removal from the device can be enhanced and at the same time, the cost of a semiconductor device can be reduced in comparison with the case where an organic interlayer film is employed.

In addition, the selectivity ratio of the cover mask 10 with respect to the organic interlayer film 6 becomes high during etching step when using a gas containing N₂/H₂. For this reason, in the step of etching the organic interlayer film 6 using the cover mask 10, shown in FIG. 3C, as a mask, even after removal of the resist film 12, the cover mask 10 serves as a mask for the lower mask 7 and the organic interlayer film 6. Thus, a region of the lower mask 7 and the organic interlayer film 6, which region is defined as excluding the region corresponding to the opening 13 of the resist film 12, can be prevented from being etched.

Furthermore, in the embodiment, the etching rate of the cover mask 10 is made lower than that of the lower mask 7. This allows the etching rate of the cover mask 10 to be lower than that of the inorganic interlayer film 5 and at the same time, permits the etching rate of the lower mask 7 to approximately be equal to that of the inorganic interlayer film 5. Making the etching rate of the cover mask 10 lower than that of the inorganic interlayer film 5 reduces an extent to which the cover mask 10 is etched during the step of etching the inorganic interlayer film 5 and prevents the erosion of the upper mask 7. Furthermore, making the etching rate of the lower mask 7 to approximately be equal to that of the inorganic interlayer film 5 reduces a time interval over which the upper mask 8 is exposed and then the lower mask 7 is processed to have the profile of an interconnect trench, preventing the erosion of the upper mask 8. As a result, a time interval required to etch and remove the upper mask 8 can be reduced and therefore, the erosion of the upper mask 8 can be suppressed.

Additionally, making the etching rate of the cover mask 10 higher than that of the upper mask 8 allows the cover mask 10 to be removed and exposed without etching the upper mask 8 at the time of completion of the etching step in the step of etching the inorganic interlayer film 5 using the cover mask 10, shown in FIG. 4A, as a mask. This allows the upper mask 8 to be used as a mask in the step of etching the organic interlayer film 6 shown in FIG. 4B and forming the interconnect trench 15, and at the same time, prevents the disappearance of the upper mask 8 during the same step, resulting in highly accurate formation of the interconnect trench 15. As a result, a fine interconnect line having a width of about 140 nm can be formed, allowing a highly integrated semiconductor device.

It should be noted that although the embodiment in which the lower mask is formed of silicon oxide and the upper mask is formed of silicon nitride is described, the present invention is not limited to the above-described embodiment. For example, the lower mask may be realized by employing silicon carbide, silicon nitride, silicon carbonitride, tungsten, tungsten silicide, silicon oxyfluoride, Hydrogen-Silsesquioxane (HSQ), Methyl-Silsesquioxane (MSQ) or Methyl-Hydroquinone (MHSQ). Furthermore, the upper mask may be realized by employing, for example, silicon carbide, silicon carbonitride, tungsten, tungsten silicide, silicon oxyfluoride, HSQ, MSQ or MHSQ. Note that when determining combination of materials used to form the lower mask, the upper mask and the cover mask, the following conditions have to be satisfied in the step of etching the inorganic interlayer film using the cover mask as a mask in order to form the via hole. That is, the etching rate of the cover mask is higher than that of the upper mask and further, lower than that of the lower mask. Thus, when the inorganic interlayer film is etched using the cover mask as a mask to form the via hole in the inorganic interlayer film, the cover mask is able to protect the upper mask from being etched until half of the step of etching the inorganic interlayer film has completed and further, remove the cover mask at the time of completion of the etching step and then expose the upper mask.

In addition, although the embodiment in which the interlayer film used in formation of interconnect line is formed of the organic interlayer film 6 is shown, the present invention is not limited to the above-described embodiment, but may employ an embodiment in which a material whose etching rate is lower than that of the interlayer film used in formation of interconnect line is selected for formation of the lower mask and then the interlayer film used in formation of interconnect line is formed of an inorganic interlayer film. In this case, both the interlayer film used in formation of via and the interlayer film used in formation of interconnect line are formed of an inorganic interlayer film, further enhancing heat removal from the device and further reducing the cost of the device. Note that it is necessary to make the etching rate of an inorganic interlayer film constituting the interlayer film used in formation of via and the etching rate of an inorganic interlayer film constituting the interlayer film used in formation of interconnect line different from one another or to form an etch-stop film between the interlayer film used in formation of via and the interlayer film used in formation of interconnect line.

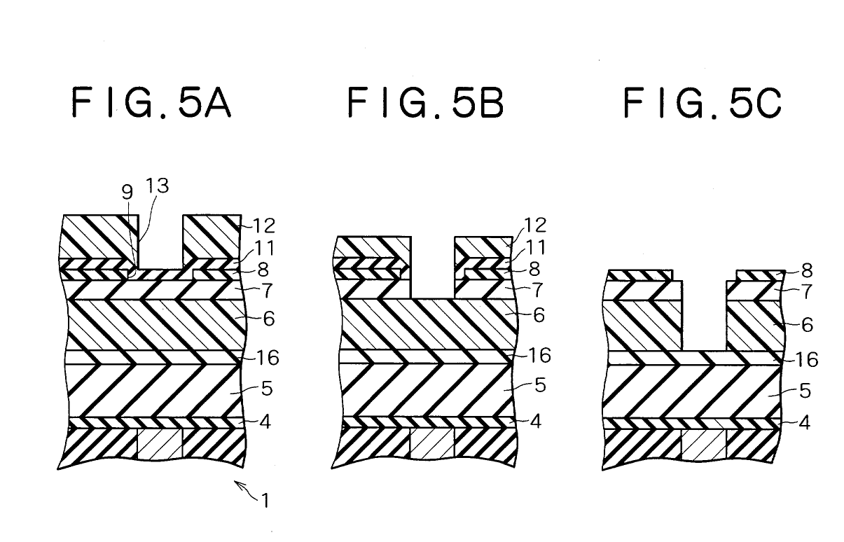

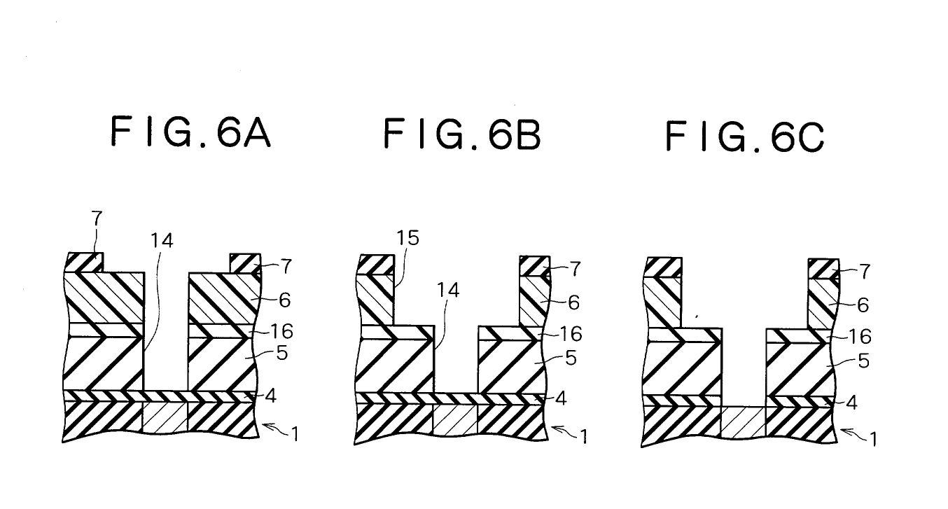

A comparative example departing from the spirit and scope of the objects of the present invention will be explained below. FIGS. 5A to 5C and FIGS. 6A to 6C are cross sectional views illustrating a method for manufacturing a semiconductor device using dual-damascene techniques in accordance with the comparative example in the order of process steps. A difference between the comparative example and the previously described embodiment is that the comparative example does not have a cover mask formed therein.

First, as shown in FIG. 5A, using process steps similar to those employed in the previously described embodiment of the present invention, a stopper film 4 and an inorganic interlayer film 5 are formed on a substrate 1. Then, a bonding layer 16 is formed on the inorganic interlayer film 5. Thereafter, using process steps similar to those employed in the previously described embodiment, an organic interlayer film 6, a lower mask 7 and an upper mask 8 are formed. An opening 9 is formed in the upper mask 8. Then, an Anti-Reflection Coating (ARC) film 11 and a resist film 12 are formed on the upper mask 8 without forming a cover mask on the upper mask 8. Subsequently, a pattern used in formation of via hole is formed in the resist film 12 to form an opening 13 in the resist film.

Thereafter, as shown in FIG. 5B, the ARC film 11 and the lower mask 7 are etched using the resist film 12 as a mask in this order and the corresponding portions of those films are selectively removed. Then, as shown in FIG. 5C, the organic interlayer film 6 is etched using the upper mask 8 as a mask and the corresponding portion of the film 6 is selectively removed. Through this etching step, the resist film 12 and the ARC film 11 (refer to FIG. 5B) also are etched and removed, and the upper mask 8 is exposed.

Subsequently, the inorganic interlayer film 5 is etched using the upper mask 8 as a mask and the corresponding portion of the film 5 is selectively removed. As a result, as shown in FIG. 6A, a via hole 14 is formed in the inorganic interlayer film 5. However, process conditions for etching the inorganic interlayer film 5 and then forming the via hole 14 make the upper mask 8 also etched. For this reason, the erosion of the upper mask 8 becomes serious and the upper mask 8 rarely remains upon completion of the-etching step. Furthermore, as the upper mask 8 disappears, the lower mask 7 is also etched and the opening of the lower mask 7 is made to largely expand.

Thereafter, as shown in FIG. 6B, the organic interlayer film 6 is etched to form an interconnect trench 15. However, at this stage, the upper mask 8 which should essentially serve as a mask almost all has disappeared and the opening of the lower mask 7 also has largely expanded. This causes the size of the interconnect trench 15 to largely be deviated in an expanding direction from its design value.

Then, as shown in FIG. 6C, using process steps similar to those employed in the previously described embodiment of the present invention, a portion of the stopper film 4 exposed through the bottom of the interconnect trench 15 is etched and removed, and a via and an interconnect line, both of which are made of copper, is formed within the via hole 14 and the interconnect trench 15, respectively. However, in this case, the width of the interconnect line becomes larger than its design value. For instance, even when the design value of the size of the interconnect trench is 140 nm, it actually becomes 180 nm.

In this way, since it is considered difficult to adjust process conditions so that the selectivity ratio of the upper mask 8 made of silicon nitride with respect to the organic interlayer film 5 becomes high and further the corresponding portion of the organic interlayer film 5 is sufficiently etched and removed, i. e., to determine process conditions under which the upper mask 8 is rarely etched and at the same time, the organic interlayer film 5 is sufficiently etched, when the corresponding portion of the inorganic interlayer film 5 is etched to form the via hole 14, the upper mask 8 is also etched accordingly. For this reason, the method employed to form the comparative example makes it difficult to make a semiconductor device have an interconnect trench whose size is not greater than 190 nm, for example, 140 nm.

It should be noted that in order to solve drawbacks contained in the comparative example, a process step of forming the upper mask 8 to a large film thickness in order to make the upper mask have high etching resistance may be employed as a counter measure. However, forming the upper mask 8 to a large film thickness increases the height of the step along the concave-convex formed on the upper surface of the ARC film 11. This causes defocusing when exposing the resist film 12 and the resist film cannot be patterned into fine structures by a lithography technique. As a result, the inorganic interlayer film 5 and the organic interlayer film 6 cannot be patterned into fine structures. To form in the resist film 12 a fine pattern used in formation of a trench of a width of 140 nm, it is required to form the upper mask 8 to a thickness of about not greater than about 80 nm to increase exposure margin.

In contrast, in the above-described embodiment of the present invention, since the cover mask 10 protects the upper mask 8 from being etched during the step of etching the inorganic interlayer film 5, the upper mask 8 is not required to have a large film thickness. Furthermore, at the time when a pattern used in formation of via hole is formed in the resist film 12, since the cover mask 10 is being formed over the substrate so as not to enhance the concave-convex profile of the surface of the upper mask 8, the height of a step formed on the surface of the ARC film 11 is never enlarged even after formation of the cover mask 10. This allows the resist film 12 to be patterned into fine structures.

Moreover, in order to solve drawbacks contained in the comparative example, a process step of forming the ARC film 11 to a large film thickness so that the ARC film serves also as the cover mask 10 may be employed as a counter measure. However, since the ARC film 11 typically is formed of an organic material, when the organic interlayer film 6 is etched, the ARC film 11 is etched and removed together with the resist film 12. Therefore, the process step of forming the ARC film 11 to a large film thickness so that the ARC film 11 serves also as the cover mask 10 cannot be employed.

What is claimed is:

1. A method for manufacturing a semiconductor device using dual-damascene techniques, comprising the steps of:
forming in order a first interlayer film made of a first inorganic low dielectric constant film and a second interlayer film made of one of an organic low dielectric constant film and a second inorganic low dielectric constant film, said second inorganic low dielectric constant film being characterized such that an etching rate of said second inorganic low dielectric constant film is different from that of said first inorganic low dielectric constant film;
forming a lower mask on said second interlayer film;
forming an upper mask having an interconnect trench formed therein on said lower mask;
forming a cover mask over surfaces of said lower mask and said upper mask;
etching said cover mask, said lower mask and said second interlayer film using as a mask a resist film having an opening formed therein for formation of a via hole;
etching said first interlayer film using said cover mask as a mask to form a via hole while removing said cover mask to make said upper mask exposed; and
etching said second interlayer film using said upper mask as a mask to form an interconnect trench.

2. A method for manufacturing a semiconductor device using dual-damascene techniques, comprising the steps of:
forming in order a first interlayer film made of a first inorganic low dielectric constant film and a second interlayer film made of one of an organic low dielectric constant film and a second inorganic low dielectric constant film, said second inorganic low dielectric constant film being characterized such that an etching rate of said second inorganic low dielectric constant film is different from that of said first inorganic low dielectric constant film;
forming a lower mask on said second interlayer film;
forming an upper mask having an interconnect trench formed therein on said lower mask;
forming a cover mask made of a material over surfaces of said lower mask and said upper mask, said material being characterized such that an etching rate of said material is between etching rates of said lower mask and said upper mask;
etching said cover mask, said lower mask and said second interlayer film using as a mask a resist film having an opening formed therein for formation of a via hole;
etching said first interlayer film using said cover mask as a mask to form a via hole; and
etching said second interlayer film using said upper mask as a mask to form an interconnect trench.

3. A method for manufacturing a semiconductor device using dual-damascene techniques, comprising the steps of:
forming in order a first interlayer film made of a first inorganic low dielectric constant film, an etch stop film and a second interlayer film made of one of an organic low dielectric constant film and a second inorganic low dielectric constant film;
forming a lower mask on said second interlayer film;
forming an upper mask having an interconnect trench formed therein on said lower mask;
forming a cover mask over surfaces of said lower mask and said upper mask;
etching said cover mask, said lower mask and said second interlayer film using as a mask a resist film having an opening formed therein for formation of a via hole;
etching said first interlayer film using said cover mask as a mask to form a via hole while removing said cover mask to make said upper mask is exposed; and
etching said second interlayer film using said upper mask as a mask to form an interconnect trench.

4. A method for manufacturing a semiconductor device using dual-damascene techniques, comprising the steps of:
forming in order a first interlayer film made of a first inorganic low dielectric constant film, an etch stop film and a second interlayer film made of one of an organic low dielectric constant film and a second inorganic low dielectric constant film;
forming a lower mask on said second interlayer film;
forming an upper mask having an interconnect trench formed therein on said lower mask;
forming a cover mask made of a material over surfaces of said lower mask and said upper mask, said material being characterized such that an etching rate of said material is between etching rates of said lower mask and said upper mask;
etching said cover mask, said lower mask and said second interlayer film using as a mask a resist film having an opening formed therein for formation of a via hole;
etching said first interlayer film using said cover mask as a mask to form a via hole; and
etching said second interlayer film using said upper mask as a mask to form an interconnect trench.

5. The method for manufacturing a semiconductor device using dual-damascene techniques according to claim 1, further comprising the step of: forming an Anti-Reflection Coating film on said cover mask after formation of said cover mask, wherein said resist film is formed after formation of said Anti-Reflection Coating film.

6. The method for manufacturing a semiconductor device using dual-damascene techniques according to claim 1, wherein the step of etching said cover mask, said lower mask and said second interlayer film using as a mask a resist film having an opening formed therein for formation of a via hole includes the steps of:
etching said cover mask and said lower mask using said resist film as a mask; and
etching said second interlayer film using said resist film as a mask while removing said resist film to make said cover mask exposed.

7. The method for manufacturing a semiconductor device using dual-damascene techniques according to claim 1, wherein said cover mask is made of at least one selected from a group consisting of silicon oxynitride, silicon nitride, silicon carbide, silicon carbonitride and silicon oxide.

8. The method for manufacturing a semiconductor device using dual-damascene techniques according to claim 1, wherein said cover mask is formed to have a film thickness of 20 to 100 nm.

9. The method for manufacturing a semiconductor device using dual-damascene techniques according to claim 1, wherein said lower mask is made of at least one selected from a group consisting of silicon oxide, silicon carbide, silicon nitride, silicon carbonitride, tungsten, tungsten silicide, silicon oxyfluoride, Hydrogen-Silsesquioxane (HSQ), Methyl-Silsesquioxane (MSQ) and Methyl-Hydroquinone (MHSQ).

10. The method for manufacturing a semiconductor device using dual-damascene techniques according to claim 1, wherein said upper mask is made of at least one selected from a group consisting of silicon nitride, silicon carbide, silicon carbonitride, tungsten, tungsten silicide, silicon oxyfluoride, Hydrogen-Silsesquioxane (HSQ), Methyl-Silsesquioxane (MSQ) and Methyl-Hydroquinone (MHSQ).

11. The method for manufacturing a semiconductor device using dual-damascene techniques according to claim 7, wherein said lower mask is made of silicon oxide, said upper mask is made of silicon nitride and said cover mask is made of silicon oxynitride.

12. The method for manufacturing a semiconductor device using dual-damascene techniques according to claim 1, wherein said first interlayer film is made of one of Methyl-Silsesquioxane and silicon oxide.

13. The method for manufacturing a semiconductor device using dual-damascene techniques according to claim 1, wherein said second interlayer film is made of one of polyphenylene and polyarylether.

14. The method for manufacturing a semiconductor device using dual-damascene techniques according to claim 1, wherein said second interlayer film is made of one of Methyl-Silsesquioxane and silicon oxide.
